(19) United States
(12) Patent Application Publication
(10) Pub. No.: US 2025/0081647 A1
(43) Pub. Date: Mar. 6, 2025

(54) IMAGE SENSOR PACKAGES AND RELATED METHODS

(71) Applicant: SEMICONDUCTOR COMPONENTS INDUSTRIES, LLC, Scottsdale, AZ (US)

(72) Inventors: Soon Wei WANG, Seremban (MY); Jin Yoong LIONG, Seremban (MY); Kai Chat TAN, TANGKAK (MY); May May GAN, Tanah Merah (MY)

(73) Assignee: SEMICONDUCTOR COMPONENTS INDUSTRIES, LLC, Scottsdale, AZ (US)

(21) Appl. No.: 18/462,082

(22) Filed: Sep. 6, 2023

(51) Int. Cl. H01L 27/146; H01L 23/00

(52) U.S. Cl. CPC H10F 39/804; H01L 24/29; H01L 24/32; H01L 24/48; H01L 24/73; H01L 24/83; H10F 39/011; H01L 24/33; H01L 2224/29035; H01L 2224/2919; H01L 2224/32225; H01L 2224/33181; H01L 2224/48225; H01L 2224/73215; H01L 2224/73265; H01L 2224/83191; H01L 2224/83862; H01L 2224/83874; H01L 2924/0665

(57) ABSTRACT

Implementations of an image sensor package may include an optically transmissive cover including a groove along an entire perimeter of the optically transmissive cover; an image sensor die; an adhesive material coupling the optically transmissive cover to the image sensor die; and a mold compound contacting sidewalls of the image sensor die, contacting the adhesive material, and extending into the groove.

### BACKGROUND

### 1. Technical Field

Aspects of this document relate generally to image sensor devices, such as devices for sensing electromagnetic radiation.

### 2. Background

Packages for semiconductor devices have been devised to protect semiconductor die from a variety of environmental conditions including electrostatic discharge and humidity. Semiconductor packages also have been developed that provide electrical routing from the semiconductor die to a circuit board or motherboard to which the semiconductor package is mounted.

### SUMMARY

Implementations of an image sensor package may include an optically transmissive cover including a groove along an entire perimeter of the optically transmissive cover; an image sensor die; an adhesive material coupling the optically transmissive cover to the image sensor die; and a mold compound contacting sidewalls of the image sensor die, contacting the adhesive material, and extending into the groove.

Implementations of an image sensor package may include one, all, or any of the following:
The package may include a substrate coupled to the image sensor die.
The substrate may include a ball grid array.
The substrate may include a ball grid array.
An outer edge of the package may include only mold compound and the substrate.
The plurality of wire bonds may be located in the adhesive material.
The groove may be located adjacent a largest planar side of the optically transmissive cover that may be opposite a largest planar side that faces the image sensor die.

Implementations of a method of making an image sensor package may include providing an optically transmissive cover including a groove along an entire perimeter of the optically transmissive cover and an image sensor die; applying an adhesive material along a perimeter of the image sensor die; contacting the optically transmissive cover to the adhesive material; irradiating the adhesive material through the optically transmissive cover with electromagnetic radiation to at least partially cure the adhesive material; and applying a mold compound to the image sensor die, the adhesive material, and into the groove.

Implementations of a method of method of making an image sensor package may include one, all, or any of the following:
The groove may be located adjacent a largest planar side of the optically transmissive cover that may be opposite a largest planar side that faces the image sensor die.
The electromagnetic radiation may be ultraviolet light.
The method may include thermally curing the adhesive material.
The method may include providing a substrate and forming a plurality of wirebonds between the substrate and bond pads included on the image sensor die.
Applying the adhesive material may further include applying the adhesive material over the plurality of wirebonds.

Implementations of a method of making an image sensor package may include providing an optically transmissive panel; cutting a first set of grooves into the optically transmissive panel in a first direction; cutting a second set of grooves into the optically transmissive panel in a second direction; and singulating the optically transmissive panel in the first set of grooves in the first direction. The method may also include singulating the optically transmissive panel in the second set of grooves in the second direction to form a plurality of optically transmissive covers. The first width of the first set of grooves and a second width of the second set of grooves may form a step along an entire perimeter of each optically transmissive cover of the plurality of optically transmissive covers.

Implementations of a method of making an image sensor package may include one, all, or any of the following:
The first set of grooves and the second set of grooves may be sawn.
Singulating further may include sawing.
The first width and the second width may be the same.
The first width and the second width may be different.

The method may further include: providing an image sensor die; applying an adhesive material along a perimeter of the image sensor die; bonding the optically transmissive cover to the adhesive material; irradiating the adhesive material with electromagnetic radiation to at least partially cure the adhesive material; and applying a mold compound into the step of the optically transmissive cover.

The method may further include: providing a substrate; forming a plurality of wirebonds between the substrate and bond pads included on the image sensor die; and applying the adhesive material over the plurality of wirebonds.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a diagram of an implementation of a method of making an optically transmissive cover;

FIG. 2 is a diagram of an implementation of a method of making an optically transmissive cover;

FIG. 3 is a perspective view of an implementation of an optically transmissive cover;

FIG. 4 is a cross sectional view of the optically transmissive cover implementation of FIG. 3;

FIG. 5 is a top view an implementation of an optically transmissive cover;

FIG. 6 is a side cross sectional view of an implementation of image sensor die coupled to a substrate;

FIG. 7 is a cross sectional view of the implementation of the image sensor package of FIG. 6 following formation of wirebonds and application of adhesive material;

FIG. 8 is a cross sectional view of the implementation of the image sensor package of FIG. 7 following coupling of an optically transmissive cover to the adhesive material;

FIG. 9 is a cross sectional view of the implementation of the image sensor package of FIG. 8 following application of a mold compound;

FIG. 10 is a cross sectional view of two implementations of image sensor packages following application of mold compound during a singulation process;

FIG. 11 is a cross sectional view of two image sensor packages that are not wire-in-dam image sensor packages;

FIG. 12 is a cross sectional view of two image sensor packages, one of which is a ball grid array package and the other a land grid array package; and

FIG. 13 is a cross sectional view another image sensor package showing a slope of the mold compound.

### DESCRIPTION

This disclosure, its aspects and implementations, are not limited to the specific components, assembly procedures or method elements disclosed herein. Many additional components, assembly procedures and/or method elements known in the art consistent with the intended image sensor packages and related methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such image sensor packages, and implementing components and methods, consistent with the intended operation and methods.

Flare is the term used for image artifacts created by stray light received by a pixel array of an image sensor. Flare caused by package components is a concern in various image sensor applications, particularly those used in advanced driver-assistance systems and autonomous driving systems as this source of flare is not caused by environmental factors, but by the package structure itself. As the package components go with the image sensor wherever it goes, minimizing the chances that flare can be caused by package components can be an important package design consideration. Those components that have been observed to help create flare are the edge of the optically transmissive cover over the image sensor die, the bead/edge of the adhesive material, bond wires, wire bonds, and/or bond pads.

In various image sensor package implementations, flare caused by package components can be mitigated by the use of a black mask under glass structure where an optically black mask layer is applied around the perimeter of an optically transmissive cover. This technique is used in wire-in-dam package implementations where the bond wires, wire bonds, and bond pads are located under the adhesive material holding the optically transmissive cover and image sensor die together. One of the primary challenges with the black mask under glass technique is that the black mask material makes performing an ultraviolet (UV) light curing process with the adhesive material more difficult, as the black mask itself absorbs the curing light.

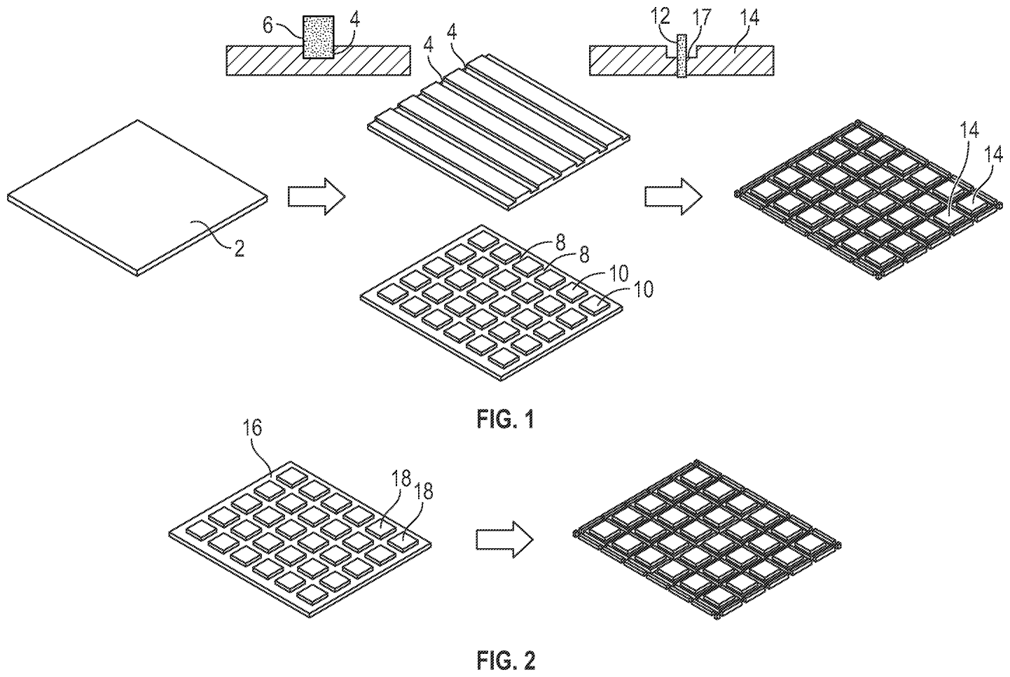

The package and method implementations disclosed herein contain various structures designed to help mitigate flare caused by package components. Referring to FIG. 1, a flow chart of a method of creating optically transmissive covers for image sensor package implementations like those disclosed herein is illustrated. FIG. 1 illustrates an optically transmissive panel 2 that is made of a material that is transmissive to the particular wavelength(s) of electromagnetic radiation that the optical sensor package is designed to detect. In various implementations, these wavelengths may include, by non-limiting example, visible light, ultraviolet light, infrared light, x-rays, microwaves, laser light, or any other type of electromagnetic radiation. While the use of a square panel is illustrated in FIG. 1, the optically transmissive panel 2 may take the form of a circle or other wafer-shaped product where wafer scale processing techniques are be utilized

As illustrated in FIG. 1, a first set of grooves 4 is cut into the material of the optically transmissive panel 2 using a saw blade 6 with a first kerf width in a first direction. While the use of sawing is illustrated for forming the first set of grooves 4, other methods of removing the material of the optically transmissive panel 2 could be used in various method implementations, including, by non-limiting example, lasering, water jet cutting, etching, scribing, any combination thereof, or any other technique for removing the material of the optically transmissive panel 2. As illustrated in FIG. 1, a second set of grooves 8 are then cut into the material of the optically transmissive panel 2 using saw blade 6 with the first kerf width in a second direction that crosses the first direction that forms a set of islands 10 in the material of the optically transmissive panel 2. The first set of grooves 4 and second set of grooves 8 are each cut to a width. In the implementation of FIG. 1, the width of the first set of grooves 4 and the width of the second set of grooves 8 is the same, as they are cut using the same saw blade with the same kerf width. In other implementations, however, the width of the first set of grooves 4 and the width of the second set of grooves 8 may be different to allow for the dimensions of the step cut into each optically transmissive panel 2 to be differ on two sides as will be discussed in more detail hereafter.

Referring again to FIG. 1, the optically transmissive panel 2 with the islands 10 formed therein is then cut using a second saw blade 12 with a narrower kerf width than the kerf width of the first saw blade 6. The second cut is all the way through the material of the optically transmissive panel 2, singulating a plurality of optically transmissive covers 14 from the optically transmissive panel 2. The effect of cutting with the narrow kerf width blade is to form a step cut that creates a step or groove 17 on each side of each optically transmissive cover that extends all the way around the perimeter of each optically transmissive cover.

The method implementation of FIG. 1 utilizes a two step cutting process to form the steps or grooves in the optically transmissive cover. Referring to FIG. 2, another method implementation is illustrated that utilizes an optically transmissive panel 16 that has had islands 18 prefabricated into it, meaning they have been formed by some other process than a cutting/etching/ablating process. Example of process for prefabricating the islands include, by non-limiting example, molding, casting, welding, gluing, or any other method of forming the islands in the particular material of the optically transmissive panel 16. As illustrated in FIG. 2, the areas in between the islands 18 of the optically transmissive panel 16 are then cut through using any method of singulating disclosed in this document to leave a step or groove around each of the resulting optically transmissive covers.

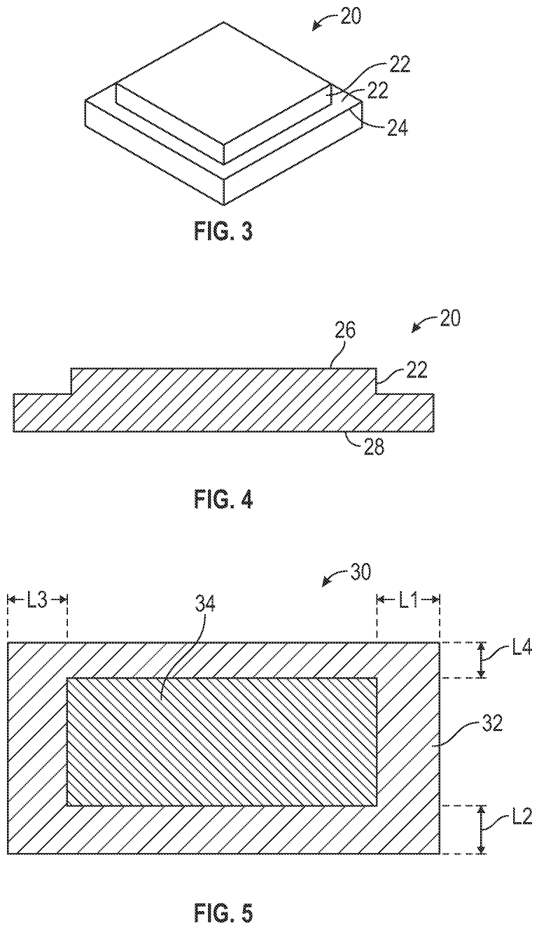

Referring to FIG. 3, an implementation of an optically transmissive cover 20 is illustrated that has been formed using either of the method implementations of FIGS. 1 and 2. As illustrated, the optically transmissive cover 20 includes a groove or step 22 that extends all the way round the perimeter 24 of the cover. FIG. 4 illustrates a cross sectional view of the optically transmissive cover 20 that shows the shape of the groove or step 22. In various package implementations, the side of the optically transmissive cover in which the groove or step 22 is formed in is the largest planar side 26 that is opposite the largest planar side 28 of the optically transmissive cover 20 that will ultimately face the image sensor die.

FIG. 5 illustrates a top down view of an implementation of an optically transmissive cover 30 that has a groove/step 32 that has different dimensions into the material of the optically transmissive cover 30. By inspection, the distances/widths L1 and L3 are the same while the distance/width L2 and L4 are different from each other and from distances/widths L1 and L3. The different widths may be more easily formed using the method implementation of FIG. 2 where the shape of the islands is prefabricated, allowing any or all of the distance/widths L1, L2, L3, L4 to be the same as one another or all be different. The different widths can be manufactured using the method implementation of FIG. 1, but the indexing of the sawing cuts may need to be adjusted in one or both of the cutting directions to singulate one side of the optically transmissive cover 30 closer to the island 34 than the other side. Those of ordinary skill in the art will readily appreciate how to create grooves/steps with different widths using the optically transmissive cover formation method implementations disclosed herein.

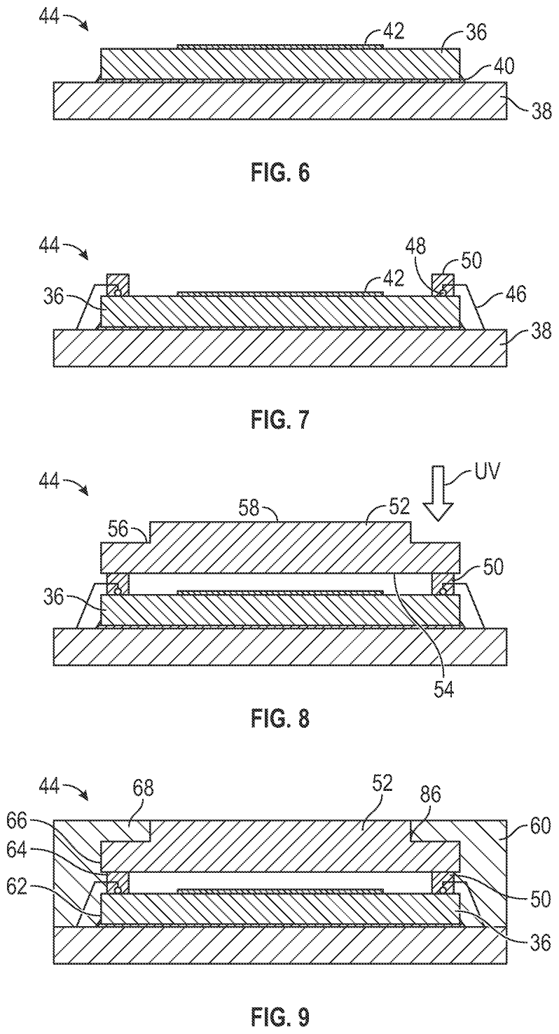

The optically transmissive cover implementations disclosed herein may be utilized in various implementations of a method of making image sensor packages. Referring to FIG. 6, an implementation of an image sensor die 36 bonded to substrate 38 using die attach material 40. As illustrated, the image sensor die 36 includes pixel array 42. Here, the die attach operation has been completed that bonds the image sensor die 36 to the substrate that begins formation of image sensor package 44. FIG. 7 illustrates the image sensor package 44 following the completion of wirebonding which attaches bond wires 46 to bond pads (not visible in FIG. 7) using wirebonds 48. As illustrated in FIG. 7, following wirebonding to the substrate 38, adhesive material 50 is applied over the wirebonds 48, bond wires 46, and bond pads around the perimeter of the image sensor die 36. In various implementations the adhesive material is a glass attach epoxy. Various implementations of adhesive materials may be partially or fully curable using ultraviolet light (UV) light and partially or fully curable using thermal energy. For those implementations where the adhesive material is partially curable using UV light and the fully curable by thermal energy, the use of UV light assists with reducing the total thermal energy that is applied to the image sensor package. Where the adhesive material is completely cured using thermal energy alone, in some image sensor package implementations, the optically transmissive cover can separate from the adhesive material leaving gaps that permit contaminants to enter the air gap where the pixel array 42 is located. Thus, the ability to complete the UV cure process of the adhesive process can be quite important to the overall reliability and function of the image sensor package.

Referring to FIG. 8, the image sensor package 44 of FIG. 7 is illustrated following coupling of the optically transmissive cover 52 to the adhesive material 50. In some implementations, this is accomplished by dropping the optically transmissive cover 52 onto the adhesive material 50. In other method implementations, the optically transmissive cover may be placed directly onto the adhesive material 50. Note that the largest planar surface 54 of the optically transmissive cover 52 that faces the image sensor die 36 does not include the groove/step 56 therein, but the opposing large planar surface 58 does. Since the optically transmissive cover 52 is optically transmissive, ultraviolet light can pass through it without significant attenuation in various implementations. Here the UV light is being irradiated onto the image sensor package to carry out the UV cure process of the adhesive material 50. Since there is no black mask layer adjacent to or covering the adhesive material in the optical path of the UV light, the UV irradiation system utilized may be any of a wide variety of systems that direct light down onto the image sensor package 44.

Following UV curing (and, in some implementations, thermal curing) of the adhesive material 50, FIG. 9 illustrates the image sensor package 44 following application of a mold compound 60 to the image sensor die 36, the adhesive material 50, and into the groove/step 56 of the optically transmissive cover 52. Here the mold compound 60 contacts the sidewall 62 of the mage sensor die 36, the sidewall 64 of the adhesive material 50, and the sidewall 66 of the optically transmissive cover 52. As illustrated, the mold compound 60 extends into the groove/step 56 and thereby forms a mask layer 68 that extends around the perimeter of the optically transmissive cover 52 over the adhesive material 50. As the mold compound 60 is optically opaque, the effect of the mold compound 60 may be substantially identical in optical performance as the black mask layer previously discussed. However, because the mask layer 68 is formed after the UV cure process for the adhesive material 50 is completed, it does not cause any issues noted with incomplete curing of the adhesive material 50. In various method implementations, the mold compound 60 is applied using a black liquid encapsulant material or using an epoxy molding compound (EMC) in an encapsulation process or using a film assisted molding (FAM) process.

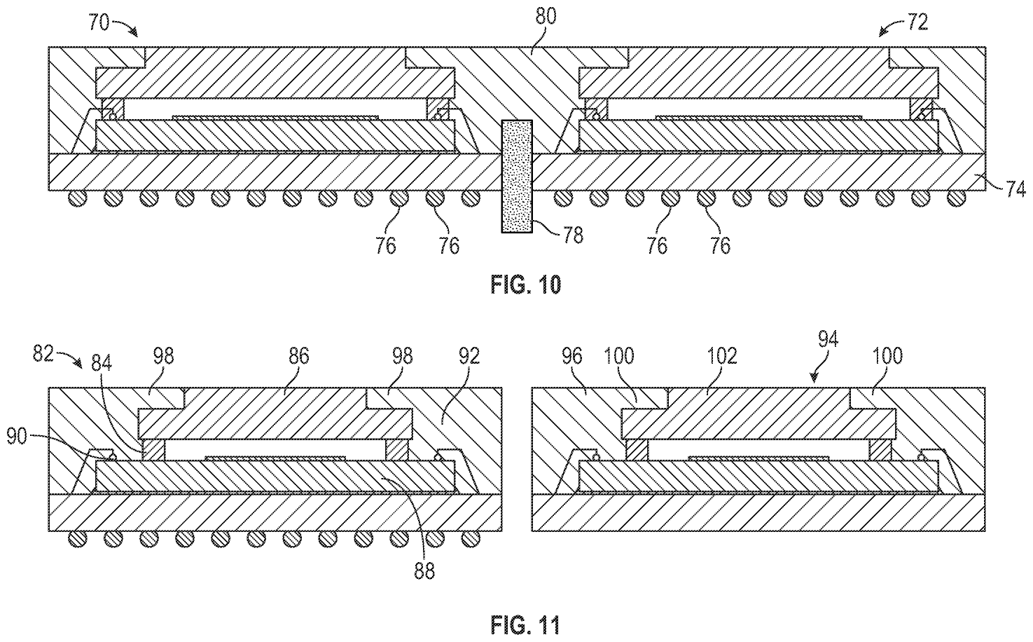

Referring to FIG. 10, two image sensor packages 70, 72 are illustrated that have been formed on a panel substrate 74 following a ball mount/ball attach process which mounts/attaches a plurality of solder balls 76 to the panel substrate 74. In FIG. 10, a sawing operation is illustrated where saw blade 78 is cutting through the material of the panel substrate 74 and the mold compound 80 to form two image sensor packages.

While the foregoing examples of image sensor packages thus far in the document have been wire-in-dam packages, the principles disclosed herein can be applied to many other image sensor types/configurations. For example, FIG. 11 illustrates a first image sensor package 82 that is a ball grid array package formed similar to that illustrated in FIGS. 6-10 but which has the adhesive material 84 located much closer to the pixel array and uses a correspondingly smaller perimeter optically transmissive cover 86 relative to the size of the image sensor die 88 than the implementations previously illustrated. Because of this, the wirebonds 90 are not located in the adhesive material 84 but are located in the mold compound 92. FIG. 11 also illustrates a second image sensor package implementation 94 that is similar in structure to the first image sensor package 82 but is a land grid array package rather than a ball grid array package. In both packages, the mold compound 92, 96 form the mask layers 98, 100 around the perimeter of the optically transmissive covers 86, 102 through the groove/step in each of the covers.

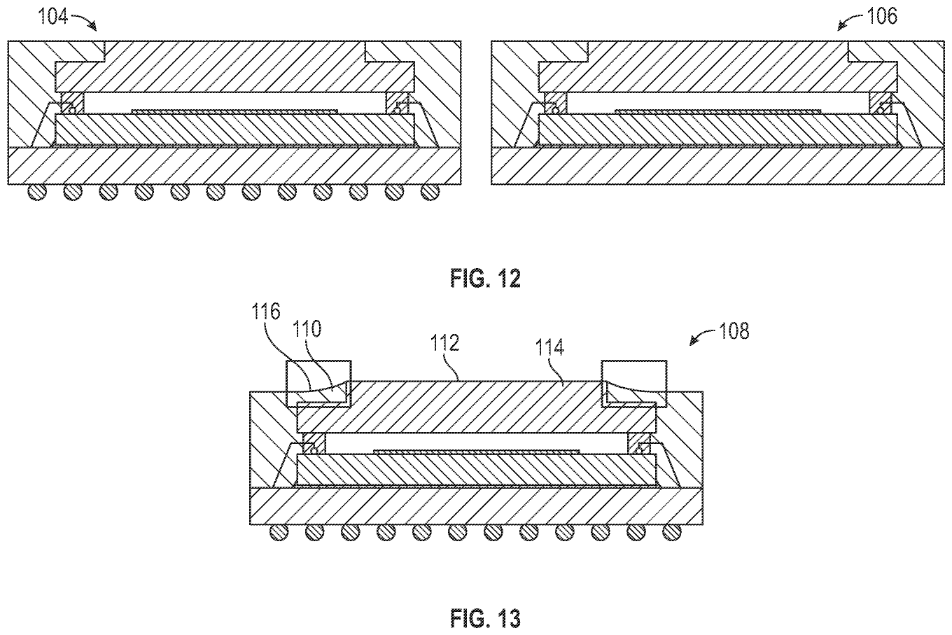

Referring to FIG. 12, two implementations of wire-in-dam image sensor packages 104, 106 are illustrated. Image sensor package 104 is a ball grid array package similar to that illustrated in FIG. 10, while image sensor package 106 is a land grid array package. FIGS. 11 and 12 illustrates that the principles disclosed herein and the optically transmissive covers disclosed herein can be used with both ball grid array and land grid array packages and with wire-in-dam packages as well as those where the wirebonds are not located in the adhesive material/dam that couples the optically transmissive cover to the image sensor die.

Referring to FIG. 13, another implementation of an image sensor package 108 is illustrated. Here, the two areas in the boxed regions show that in particular implementations, a slope 116 can exist in the mask layer 110 away from the top surface 112 of the optically transmissive cover 114. This slope may be created during the particular mold compound application process. Here, this implementation utilized a liquid encapsulant molding process which caused flow of the material away from the top surface 112 of the optically transmissive cover 114. However, even though the resulting mask layer 110 is thinner than in the implementations illustrated in FIG. 12, for example, it is sufficiently thick to act as an optical mask for scattered light.

The image sensor package implementations illustrated in FIGS. 11-13 all show cross sections where the width of the mask layer formed is the same on both sides of the package. Referring back to FIG. 5, where the widths of L1, L2, L3, and L4 differ from one another, mask layers with corresponding different widths can also be formed. This can be significant because in various image sensor die implementations, the pixel array is not actually centered on the center of the image sensor die itself due to routing, interconnect, or other design/process factors. Thus, the ability to create mask layers that are wider and thinner on different sides of the die by using optically transmissive covers with corresponding wider and thinner widths L1, L2, L3, and L4 may be advantageous. These mask layers with different widths on different sides of the optically transmissive cover may help further assist with preventing stray light from creating flare defects during operation of the image sensor package.

In places where the description above refers to particular implementations of image sensor packages and implementing components, sub-components, methods and sub-methods, it should be readily apparent that a number of modifications may be made without departing from the spirit thereof and that these implementations, implementing components, sub-components, methods and sub-methods may be applied to other image sensor packages.

What is claimed is:

1. An image sensor package comprising:
an optically transmissive cover comprising a groove along an entire perimeter of the optically transmissive cover;
an image sensor die;
an adhesive material coupling the optically transmissive cover to the image sensor die; and
a mold compound contacting sidewalls of the image sensor die, contacting the adhesive material, and extending into the groove.

2. The package of claim 1, further comprising a substrate coupled to the image sensor die.

3. The package of claim 2, wherein the substrate comprises a ball grid array.

4. The package of claim 2, wherein the substrate comprises a land grid array.

5. The package of claim 2, wherein an outer edge of the package comprises only mold compound and the substrate.

6. The package of claim 1, wherein a plurality of wire bonds are located in the adhesive material.

7. The package of claim 1, wherein the groove is located adjacent a largest planar side of the optically transmissive cover that is opposite a largest planar side that faces the image sensor die.

8. A method of making an image sensor package comprising:
providing an optically transmissive cover comprising a groove along an entire perimeter of the optically transmissive cover and an image sensor die;
applying an adhesive material along a perimeter of the image sensor die;
contacting the optically transmissive cover to the adhesive material;
irradiating the adhesive material through the optically transmissive cover with electromagnetic radiation to at least partially cure the adhesive material; and
applying a mold compound to the image sensor die, the adhesive material, and into the groove.

9. The method of claim 8, wherein the groove is located adjacent a largest planar side of the optically transmissive cover that is opposite a largest planar side that faces the image sensor die.

10. The method of claim 8, wherein the electromagnetic radiation is ultraviolet light.

11. The method of claim 8, further comprising thermally curing the adhesive material.

12. The method of claim 8, further comprising providing a substrate and forming a plurality of wirebonds between the substrate and bond pads comprised on the image sensor die.

13. The method of claim 12, wherein applying the adhesive material further comprises applying the adhesive material over the plurality of wirebonds.

14. A method of making an image sensor package comprising:
providing an optically transmissive panel;
cutting a first set of grooves into the optically transmissive panel in a first direction;
cutting a second set of grooves into the optically transmissive panel in a second direction;
singulating the optically transmissive panel in the first set of grooves in the first direction; and
singulating the optically transmissive panel in the second set of grooves in the second direction to form a plurality of optically transmissive covers;
wherein a first width of the first set of grooves and a second width of the second set of grooves forms a step along an entire perimeter of each optically transmissive cover of the plurality of optically transmissive covers.

15. The method of claim 14, wherein the first set of grooves and the second set of grooves are sawn.

16. The method of claim 14, wherein singulating further comprises sawing.

17. The method of claim 14, wherein the first width and the second width are the same.

18. The method of claim 14, wherein the first width and the second width are different.

19. The method of claim 14 further comprising:
providing an image sensor die;
applying an adhesive material along a perimeter of the image sensor die;
bonding the optically transmissive cover to the adhesive material;
irradiating the adhesive material with electromagnetic radiation to at least partially cure the adhesive material; and
applying a mold compound into the step of the optically transmissive cover.

20. The method of claim 19, further comprising:
providing a substrate;
forming a plurality of wirebonds between the substrate and bond pads comprised on the image sensor die; and
applying the adhesive material over the plurality of wirebonds.
